(19) United States
(12) Patent Application Publication
(10) Pub. No.: US 2013/0163788 A1
(43) Pub. Date: Jun. 27, 2013

(54) POWER SUPPLY CIRCUITS FOR AUDIO AMPLIFIERS

(71) Applicants: John B. French, Caledon East (CA); Farhad Gholami, Richmond Hill (CA); Andrew J. Mason, Bolton (CA); Douglas W. Hansen, Barrie (CA); Gennady H. Kalyta, Toronto (CA); Xue Jun Liu, Brampton (CA)

(72) Inventors: John B. French, Caledon East (CA); Farhad Gholami, Richmond Hill (CA); Andrew J. Mason, Bolton (CA); Douglas W. Hansen, Barrie (CA); Gennady H. Kalyta, Toronto (CA); Xue Jun Liu, Brampton (CA)

(21) Appl. No.: 13/681,887

(22) Filed: Nov. 20, 2012

Related U.S. Application Data
(63) Continuation of application No. PCT/CA2011/050314, filed on May 20, 2011.
(60) Provisional application No. 61/346,732, filed on May 20, 2010.

(51) Int. Cl. H03F 3/181

(52) U.S. Cl. CPC H03F 3/181
USPC 381/120

(57) ABSTRACT

Several amplifier power circuits and methods for powering an audio amplifier are described. An AC line voltage is rectified and selectively coupled to a filter capacitor in response to a switch control signal. The filter capacitor is charged to generate an amplifier supply voltage signal, which is used to power the audio amplifier. A controller generates the switch control signal in accordance with a leading control approach or a lagging control approach.

### FIELD

The described embodiments relate to power supply circuits for audio amplifiers, and more particularly to power supply circuits for efficiently converting a high AC line source voltage into a relatively low DC supply voltage for audio amplifiers.

### BACKGROUND

Audio amplifiers are frequently operated at relatively low voltages because the moving coil transducers driven by the audio amplifiers have generally low impedances. To power the audio amplifier using standard AC line voltages, which can be relatively high for this purpose, the AC line voltage is converted into a relatively low DC supply voltage. Due to the associated power loss, the overall efficiency of the audio amplifier can be greatly improved if this conversion between the AC line voltage and DC supply voltage can be done efficiently.

One technique for voltage conversion employs a line frequency transformer. To reduce the size and cost of the magnetic components used in the transformer, high line frequency switching can be employed. In some cases, the switching frequency can be higher line. However, high switching frequencies can generate undesirable electromagnetic emissions that introduce distortion or other harmonics into the amplified audio signal. Phase control is another technique that has been employed for transforming a high AC line voltage into a relatively low DC supply voltage. Phase control can work well when driving linear (e.g. resistive or inductive) loads, though it can tend to be less effective when driving non-linear loads such as that of an audio amplifier. Thus there is a need for a line frequency control which can work well with no linear load of an amplifier to convert the relative high voltage of the AC line to a lower more useful DC voltage to power the audio amplifier.

### SUMMARY

Embodiment according to a first aspect comprise: a power regulator, a reference signal generator a controller and an audio power amplifier. The power regulator comprises: a signal rectifier coupled to an AC power voltage source to receive an AC line voltage signal and to provide a rectified line voltage signal and a rectifier voltage signal; a filter capacitor; a controllable switch for selectively coupling the rectified line voltage signal to the filter capacitor to charge the filter capacitor in response to a switch control signal, wherein the capacitor provides a capacitor voltage signal and an amplifier supply voltage signal corresponding to the charge across the filter capacitor. The reference signal generator generates a reference voltage signal. The controller generates the switch control signal in response to the rectifier voltage signal, the capacitor voltage signal and the reference voltage signal. The audio power amplifier is coupled to the input terminal to receive the audio input signal and to the filter capacitor to receive the amplifier supply voltage signal and for generating an amplified audio signal.

In some embodiments, the audio power amplifier is selected from the group consisting of: a bridged transistor linear amplifier; a push-pull linear amplifier; and a class D amplifier.

In some embodiments, reference signal is fixed reference signal.

In some embodiments, the reference signal is floating reference signal corresponding to the audio input signal.

In some embodiments, the reference signal is floating reference signal corresponding to the audio input signal.

In some embodiments, the amplifier power supply circuit includes an input signal isolation block for providing an isolated input signal, wherein the audio power amplifier generates the amplified signal corresponding to the isolated power signal.

In some embodiments, the controller generates the switch control signal to start charging the filter capacitor in response to a zero crossing of the AC line voltage signal and to stop charging the filter capacitor when the charge on the filter capacitor corresponds to the reference voltage signal.

In some embodiments, the controller generates the switch control signal to start charging the filter capacitor in advance of a zero crossing of the AC line voltage signal and to stop charging the filter capacitor in response to the zero crossing.

Another aspect provides a method of operating an amplifier power supply circuit, the method comprising: rectifying an AC line voltage and generating a rectified line voltage signal and a rectifier voltage signal; coupling the rectified line voltage signal to a filter capacitor in response to a switch control signal; providing a capacitor voltage signal corresponding to the voltage across the capacitor; providing a reference voltage signal; generating the switch control signal in response to the rectifier voltage signal, the capacitor voltage signal and the reference voltage signal; providing an amplifier coupled to the filter capacitor, wherein the amplifier receives an amplifier supply voltage signal from the filter capacitor; and at the amplifier, amplifying an audio input signal to provide a corresponding audio output signal.

In some embodiments, the switch control signal is generated to couple the rectified line voltage signal to the filter capacitor in response to a zero crossing of the AC line voltage and to decouple the rectified line voltage signal when the charge on the filter capacitor corresponds to the reference voltage.

In some embodiments, the switch control signal is generated to couple the rectified line voltage signal to the filter capacitor in advance of a zero crossing of the AC line voltage and to decouple the rectified line voltage signal in response to the zero crossing.

Another aspect provides an audio amplifier and power supply comprising: an audio signal isolation means connected between an audio input terminal and an audio power amplifier; a circuit to provide, from a higher AC voltage source, a lower DC voltage source to power said audio power amplifier; a rectifier such as a diode bridge between the AC voltage source and a filter capacitor to provide AC to DC conversion; and a switch between the AC voltage source and Filter Capacitor to provide the high voltage to low voltage conversion.

### BRIEF DESCRIPTION OF THE DRAWINGS

A detailed description of various embodiments of the invention is provided herein below with reference to the following drawings.

FIG. 1 is a schematic diagram of an amplifier power supply circuit in accordance with embodiments of the invention.

FIG. 2 is a schematic diagram of a control block for the amplifier power supply circuit illustrated in FIG. 1.

FIG. 3 is a waveform diagram showing different signal waveforms generated by the amplifier power supply circuit illustrated in FIG. 1 using the control block illustrated in FIG. 2.

FIG. 4 is a schematic diagram of an alternative control block for the amplifier power supply circuit illustrated in FIG. 1.

FIG. 5 is a waveform diagram showing different signal waveforms generated by the amplifier power supply circuit illustrated in FIG. 1 using the control block illustrated in FIG. 4.

FIG. 6 is a schematic diagram of an alternative amplifier power supply circuit that tracks the input audio signal in accordance with embodiments of the invention.

FIG. 7 is a schematic diagram of a wireless signal processor for an amplifier power supply circuit in accordance with embodiments of the present invention.

FIG. 8A is a schematic diagram of a power regulator circuit having an integrated diode bridge, switch regulator, filter capacitor combination for use in an amplifier power supply circuit in accordance with embodiments of the present invention.

FIG. 8B is a schematic diagram of an alternative power regulator circuit having an integrated diode bridge, switch regulator, filter capacitor combination.

FIG. 8C is a schematic diagram of an alternative power regulator circuit having an integrated diode bridge, switch regulator, filter capacitor combination.

FIG. 9 is a schematic diagram of an alternative amplifier power supply circuit that utilizes a supplemental regulator in accordance with embodiments of the invention.

It will be understood that the drawings are exemplary only. All reference to the drawings is made for the purpose of illustration only and is not intended to limit the scope of the embodiments described herein below in any way. For convenience, reference numerals may also be repeated (with or without an offset) throughout the figures to indicate analogous components or features.

### DESCRIPTION OF EXEMPLARY EMBODIMENTS

Embodiments of the present invention provide a power supply circuit for an audio amplifier that is capable of converting a high AC line voltage to a relatively low amplitude, filtered DC supply voltage for an audio amplifier. The power supply circuit does not rely on large line frequency transformers or high switching frequency circuits and is compatible with non-linear loads, such as may be presented by the filter of the voltage converter, In some embodiments of the present invention, the DC supply voltage can be regulated or otherwise controlled in proportion to the input audio signal level to enhance the overall power efficiency of the amplifier.

In accordance with embodiments of the invention, a non-linear load can be coupled to an AC voltage line in order to rectify the AC line voltage signal, which can be sinusoidal. The non-linear load can be a bridge diode or some other signal rectifier. A controllable switch, for example a semiconductor switch, is coupled to the output of the diode bridge to selectively and controllably apply the rectified line voltage signal to a filter capacitor, Thus, the rectified line voltage signal can be applied to the filter capacitor only when the switch is conducting (i.e. closed), so that the capacitor voltage can effectively track the instantaneous voltage of the AC line signal during the time intervals when the switch is conducting. If the filter capacitor is coupled across a load, the filter capacitor can slowly discharge when the switch is open and non-conducting, thus causing a slow decrease in capacitor voltage.

If the semiconductor switch is closed at or near a zero crossing of the AC line voltage signal and remains closed for a short time interval relative to the period of the sinusoidal line signal, the charge on the filter capacitor will be kept relatively low in comparison to the amplitude of the AC line voltage. During intervals when the semiconductor switch conducts, the voltage actually appearing on the filter capacitor may not exactly equal the unloaded AC line voltage, for example, if the AC line source has some inductance. Current flows into the filter capacitor from the AC line source when the switch is closed and when the AC line voltage is higher than the filter capacitor voltage. However, due to the source line inductance, this charging current may take some amount of time to ramp up to its steady-state value, which can cause the above-described difference in the filter capacitor voltage.

In accordance with embodiments of the present invention, the timing of the semiconductor switch can also be controlled using at least two approaches, each approach effective in keeping the filter capacitor voltage low in comparison to the AC line source voltage. In one approach, the semiconductor switch is closed after each zero crossing and opened after the capacitor voltage exceeds a reference voltage. This control approach is referred to as “leading control” herein throughout. In another approach, the switch is closed at some point before the zero crossing and remains closed until the zero crossing occurs, at which point the switch is opened. This control approach is referred to as “lagging control” herein throughout.

Leading control involves the semiconductor switch interrupting current flowing in the AC line inductance whenever the switch is opened. Generally a more robust and complex switch can be required to avoid damaging the switch caused by the inductive spike. Overall efficiency of the power supply circuit can also be decreased if the line inductance is large.

Lagging control involves predicting how far in advance of each zero crossing to close the switch so that the correct energy is transferred to the filter capacitor each half cycle of the AC line voltage to maintain the filter capacitor at the reference voltage. A method for predicting the period in advance of each line cycle to close the switch is to integrate the past error and adjust this period to minimize the error. However, because the switch is opened at each zero crossing of the AC line voltage, the switch is no longer interrupting inductive line current. When the AC line voltage reverses polarity, the current through the switch drops to zero on its own; thus, the switch is self-commutating.

The reference voltage at which the filter capacitor is maintained can be a fixed reference voltage. However, in some embodiments, the filter capacitor voltage can be controlled to track a floating reference voltage, which can be determined by reference to the input audio signal. For example, an envelope of the input audio signal can be used as the floating reference voltage, as described in U.S. Pat. No. 7,362,168 (entitled “Audio Amplifier”) and in U.S. application Ser. No. 12/647,022 (entitled “Push-Pull Linear Class H Amplifier”), the entire contents of each of which are hereby incorporated by reference. More efficient operation of the power supply circuit can be achieved when the envelope of the input audio signal serves as the reference.

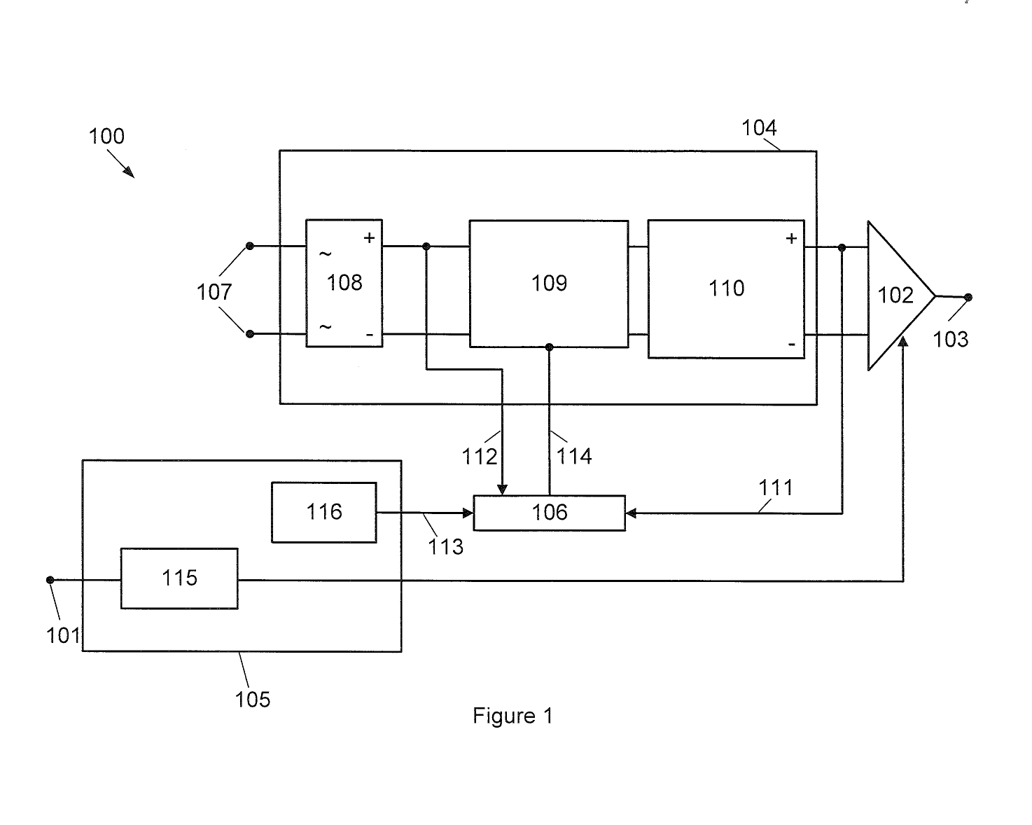

Referring now to FIG. 1, there is illustrated a schematic diagram of a first amplifier power supply circuit 100. The amplifier power supply circuit 100 includes an audio power amplifier 102, a power regulator 104, a signal processor 105, and a controller 106. The signal processor 105 is coupled to an audio input terminal 101 to receive an input audio signal, which is relayed to the audio power amplifier 102 for amplification. AC line input power terminals 107 provide the power regulator 104 with an AC line voltage signal. The power regulator 104 is coupled to power supply input terminals of the audio power amplifier 102 and, in response to control signals received from the controller 106, provides the audio power amplifier 102 with a supply voltage signal. The audio power amplifier 102 amplifies the input audio signal relayed from the signal processor 105 and generates an amplified audio signal at an amplified audio output terminal 103. Controller 106 is coupled to the signal processor 105 and to the power supply input terminals of the audio power amplifier 102 to generate control signals for the power regulator 104. The audio power amplifier can be a Bridged Transistor Linear (BTL) amplifier, or push-pull linear amplifier, for example, but could also be a class D amplifier or some other type of audio amplifier.

The power regulator 104 includes a series combination of a diode bridge 108, a regulator switch 109 and a filter capacitor 110. The AC line voltage signal, which can be sinusoidal, is received into the diode bridge 108 where it is converted to a DC full wave rectified voltage signal. In place of the diode bridge 108, a half-bridge or voltage doubler, or some other configuration of voltage rectifier, could be used. The output of the diode bridge 108 is coupled with the input of the filter capacitor 110 by way of the regulator switch 109, which opens and closes in response to a switch control signal 114 received from the controller 106. Thus, the filter capacitor 110 can be selectively and controllably connected to the AC line source to be charged by the DC full wave rectified voltage signal generated by the diode bridge 108. In this way, a charging current can flow from the AC line source to the filter capacitor 110 through the diode bridge 108 and the regulator switch 109.

If the instantaneous magnitude of the AC line voltage signal is greater than the instantaneous voltage across in the filter capacitor 110, and if the regulator switch 109 is closed and conducting current, the filter capacitor 110 will charge. The regulator switch 109 can be used to control the voltage to which the filter capacitor 110 will be charged. For example, if the duration in which the regulator switch 109 conducts current is kept small, on a line-cycle by line-cycle basis, relative to the fundamental period of the AC line source voltage, then the voltage appearing across the filter capacitor 110 can be regulated by controlling the timing of when the regulator switch 109 conducts, i.e. when it is closed and opened.

Opening the regulator switch 109 decouples the filter capacitor 110 from the diode bridge 108 and interrupts the charging current provided to the filter capacitor 110 under control of the regulator switch 109. Charge accumulated during closure of the regulator switch 109 is generally held by the filter capacitor 110, though some charge can escape due to loading of the filter capacitor 110 by the audio power amplifier 102. In combination, therefore, the diode bridge 108 and the filter capacitor 110 can act as a peak detector for the DC full wave rectified signal with a decay rate determined by the loading of the audio power amplifier 102. The voltage maintained across the filter capacitor 110, which is used as the amplifier supply voltage signal for the audio power amplifier 102, can therefore be an approximate DC voltage with some line ripple present.

As will be explained in more detail below, the regulator switch 109 can be controlled to conduct current during time intervals occurring near the zero crossings of the AC line voltage signal, when the AC line voltage signal has a relatively small amplitude compared to its peak amplitude. In this way, power regulator 104 can convert the AC line voltage signal into a relatively small DC supply voltage signal for the audio power amplifier 102. This method of voltage conversion can be generally efficient because the AC line voltage signal undergoes a zero crossing, and thus is at suitably low amplitudes, every half cycle. Leading or lagging control schemes can also be utilized for this purpose.

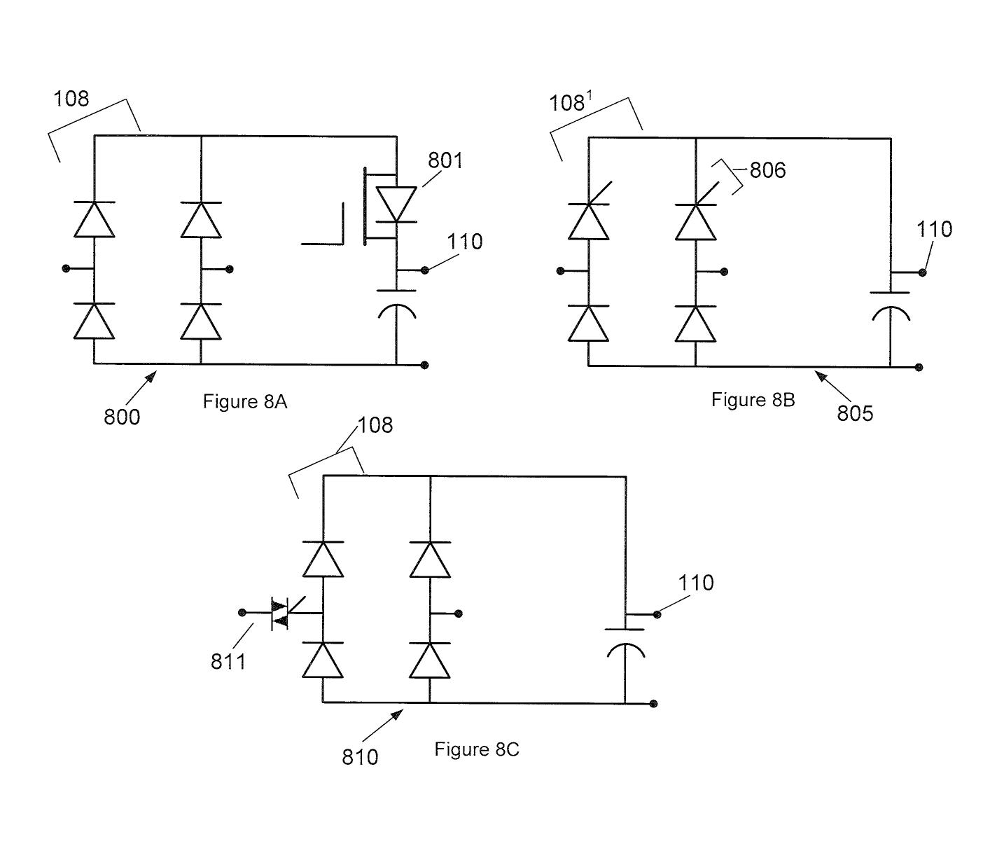

The regulator switch 109 can be typically provided using one or more semiconductor devices, such as a Metal Oxide Field Effect Transistor (MOSFET), Insulated Gate Bipolar Transistor (IGBT), Bipolar Junction Transistor (BJT), Silicon Controlled Rectifier (SCR), Triode for alternating current (Triac), and the like. The choice of semiconductor device can depend on the design objectives and, illustrated by FIGS. 8A-8C, the location of the regulator switch 109 in the power regulator 104 relative to the diode bridge 108. For example, depending on the type of semiconductor device employed, the regulator switch 109 can be provided before, as part of, or after the diode bridge 108. Other locations between the AC line input power terminals 107 and the filter capacitor 110 can be possible as well. As will be appreciated, if the AC line source has an inductance, then opening the regulator switch 109 while current is conducting can cause a voltage spike in the regulator switch 109 because the current may not drop instantaneously to zero. To prevent the occurrence of voltage spikes in the regulator switch 109, which can be quite damaging, a voltage snubber (not shown) or some other suitable circuit component can be connected across the regulator switch 109.

The timing of when the regulator switch 108 is opened and closed can be controlled using the controller 106. Accordingly, the controller can be configured to receive a capacitor voltage signal 111, a rectifier or diode bridge voltage signal 112, and a reference voltage signal 113. The capacitor voltage signal 111 can be provided by monitoring the voltage appearing across the filter capacitor 111, while the diode bridge voltage signal 112 can be provided by monitoring the output voltage of the diode bridge 108, i.e. the DC full wave rectified voltage. The reference voltage signal 113 can be generated in the signal processor 105 and can represent a desired target voltage for the filter capacitor 110. As described herein, the reference voltage signal 113 can be generated as a fixed or floating reference voltage. Based on these input signals, the controller 106 can generate the switch control signal 114 for the regulator switch 109, which can be done according to both a leading and lagging control scheme, as will be described in more detail below.

The signal processor 105 can be coupled to the input audio terminal 101 to receive the input audio signal and, on the output side, to both the controller 106 and the audio power amplifier 102. The signal processor 105 can include isolation transformer 115 for isolating the audio signal provided to the input terminals of the audio power amplifier 102. Alternatively, input signal isolation can be achieved using one or more isolation blocks or devices, such as an opto-coupler, or by passing a PWM signal through a coupling transformer. However, it should be appreciated that input signal isolation could be achieved in other ways as well. The signal processor 105 can also include fixed reference generator 116 to fix the reference voltage signal 113, used by the controller 106 to regulate the voltage appearing across the filter capacitor 110, at a level suitable for the audio power amplifier 102.

The signal processor 105 can be configured so that the input audio signal is reproduced at the input terminals of the audio power amplifier 102 proportionately and with a minimum of distortion. Thus, in some embodiments, the audio signal provided to the audio power amplifier 102 can be a scaled version of the input audio signal received at the audio input terminal 101. The reference voltage signal 113 can also be generated so that the power supply to the audio power amplifier 102, provided by the filter capacitor 110, will be optimized for a desired maximum output power of the audio power amplifier 102. The amplified output audio signal generated by the audio power amplifier 102 can thereby be an amplifier version of the input audio signal. For this purpose, the signal processor 105 can be implemented using one or both of digital and analog circuit components. As an example, a Digital Signal Processor (DSP) or other programmable processing device can be used.

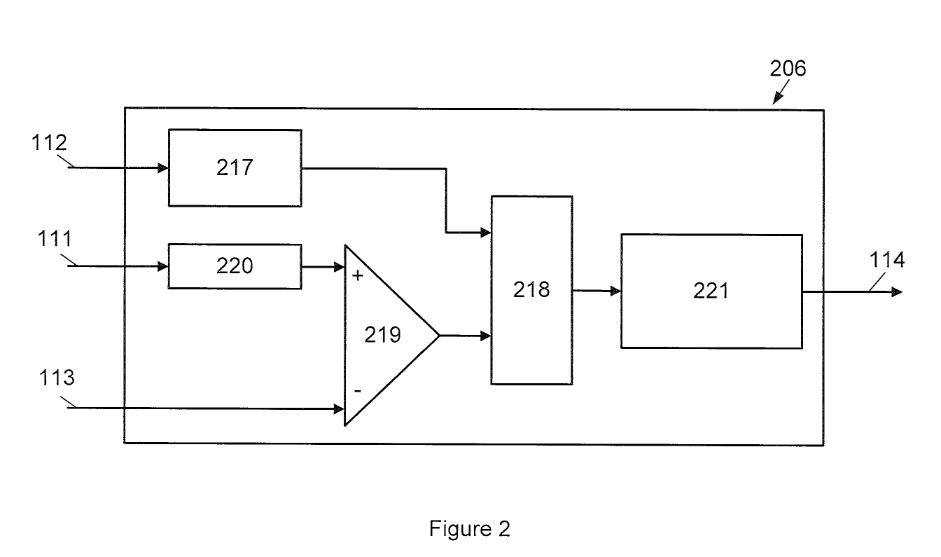

Referring now to FIG. 2, there is illustrated a controller 206 that can be used in the amplifier power supply circuit 100 to provide leading control. The controller 206 can include a zero crossing detector 217, Set/Reset (SR) latch 218, comparator 219, scalar 220 and level shift/switch driver 221. The diode bridge voltage signal 112 can be provided to the zero crossing detector 217 in order to detect when the DC full wave rectified voltage signal generated by the diode bridge 108 undergoes a zero crossing. For this purpose, the zero crossing detector 217 can generate a short duration pulse at or near each detected zero crossing of the diode bridge voltage signal 112. If the AC line source voltage is sinusoidal, the zero crossing detector 217 can generate one pulse each half cycle. The output of the zero crossing detector 217 can be coupled to the set input of the S/R latch 218, thereby setting the S/R latch 218 at a high voltage level with each zero crossing of the diode bridge voltage signal 112.

The comparator 219 can receive the capacitor voltage signal 111, scaled by the scalar 220, for comparison with the reference voltage signal 113. The output of the comparator 219 can be coupled to the reset input of the S/R latch 218. Accordingly, when the scaled version of the capacitor voltage signal 111 is higher than the reference voltage signal 113, the comparator 219 can be driven to a high voltage level to reset the S/R latch 218 to the low voltage level. The scalar 220 can be selected appropriately to downscale the generally proportionately higher voltage across the filter capacitor 110 to a level where it can be compared with the reference voltage signal 113.

The level shift/switch driver 221 can be connected to the output of the S/R latch 218 in order to convert the output signal generated by the S/R latch 218 into the switch control signal 114 for the regulator switch 109. Typically, this can involve upshifting to a level suitable for driving the control input of the semiconductor device or devices used to implement the regulator switch 109. Depending on how the regulator switch 109 is implemented, the level shift/switch driver 221 can further include driver or other control circuitry. In some embodiments, the level shift/switch driver 221 may not be required.

Accordingly, the S/R latch 218 of the controller 106 can generate the switch control signal 114 for the regulator switch 109 intermediately through the level shift/switch driver 221. When the S/R latch 218 outputs a high voltage level, corresponding to a zero crossing of the diode bridge voltage signal 112, the switch control signal 114 closes the regulator switch 109 to conduct a charging current into the filter capacitor 110. When the voltage across the filter capacitor 110 exceeds the fixed reference voltage due to overcharging, the comparator 219 causes the S/R to output a low voltage level to open the regulator switch 109. According to this leading control scheme, the regulator switch 109 is closed at the start (“leading”) of each half-cycle of the AC line source voltage and remains closed until the filter capacitor 110 has fully charged. In this way, the voltage across the filter capacitor 110 is regulated to the reference level.

It should be appreciated that the regulator switch 109 may have parasitic elements, such as a capacitance, which impose a voltage back on to the diode bridge 108. Accordingly, in some embodiments the zero crossing detector can be connected directly to the AC source line upstream of the diode bridge 108. Alternatively, in other embodiments, a diode (not shown) can be inserted after the sense between the diode bridge 108 and the regulator switch 109.

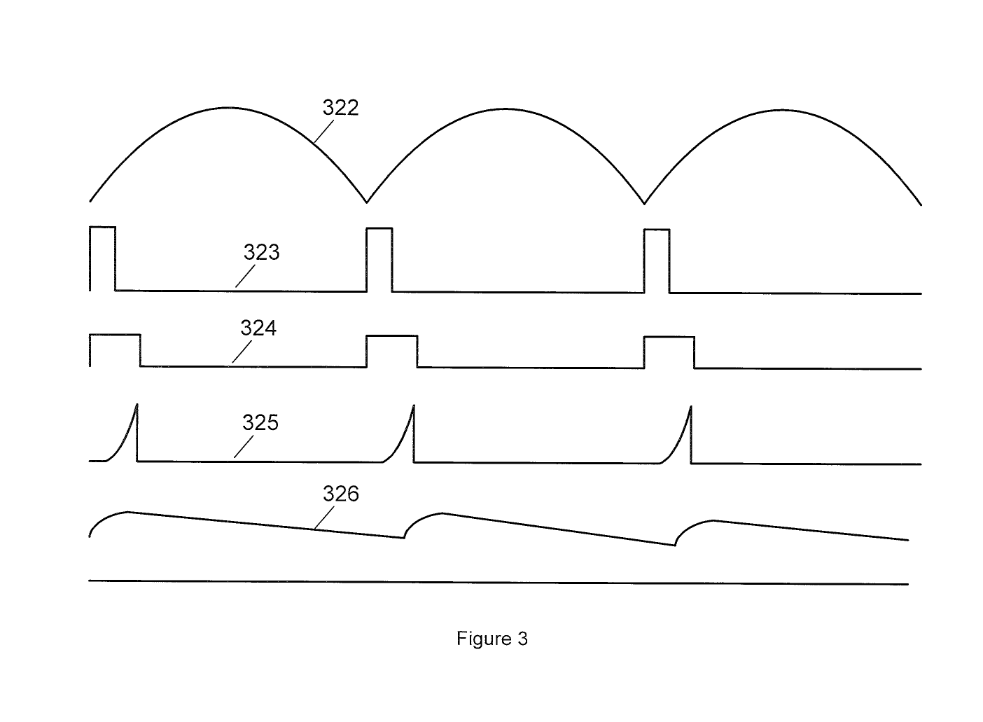

Referring now to FIG. 3, there are illustrated various signal waveforms generated in the amplifier power supply circuit 100 when the controller 206 is used to provide leading control. Waveform 322 represents the DC full wave rectified voltage provided at the output of the diode bridge 108. The peak voltage of waveform 322 can approximately equal the peak of the AC line source voltage, which would be about 365V in Europe, for example. Waveform 323 represents the output generated by the zero crossing detector 217. As can be seen, waveform 323 can comprise a pulse train with each pulse in the sequence occurring at or shortly after the AC line source voltage undergoes a zero crossing. The width of the pulses is adjustable by appropriate configuration of the zero crossing detector 217, but at a minimum should be long enough to set the S/R latch 218 to the high voltage level.

Waveform 324 represents the output generated by the S/R latch 218, and thus also can represent the switch control signal 114. Waveform 324 can also comprise a pulse train with each pulse in the sequence indicating times in which the regulator switch 109 is closed and conducting. The beginning of each pulse in waveform 324 can correspond with the zero crossings of the AC line source voltage, while the end of each pulse can correspond to the time at which the voltage on the filter capacitor 110 reaches the reference level. As can be seen, the pulses in waveform 324 occur at the start of each half-cycle of the AC line source voltage, corresponding to the repetition rate of waveform 322.

As described herein, closing of the regulator switch 109 can initiate the charging current in filter capacitor 110, which is represented by waveform 325. Accordingly, waveform 325 can also comprise a pulse train with each pulse in the sequence representing the amplitude of the charging current. The charging current gradually rises from zero at the start of each charge cycle, and is sharply reduced to zero again at the end of the cycle due to opening of the regulator switch 109.

Finally, waveform 326 represents the voltage across the filter capacitor 110, which can be regulated at an approximately constant value but having some ripple. Thus, waveform 326 can climb somewhat quickly in response to the charging current when the regulator switch 109 is closed, and gradually fall when the regulator switch 109 is opened and the filter capacitor 110, now decoupled from the diode bridge 108, is discharged due to loading by the audio power amplifier 102. The cycle of charge and discharge can cause the voltage ripple seen in waveform 326. Because the filter capacitor 110 is charged at or shortly after zero crossings of the AC line source voltage, when the AC line source voltage can be much less than its peak value, the regulated amplitude of waveform 326 can typically be much smaller than the full voltage available (e.g. 365V) from the diode bridge 108. The regulated value can depend on the requirements of the audio power amplifier 102, which is typically included in some sort of integrated circuit package, and for example could be about 50V.

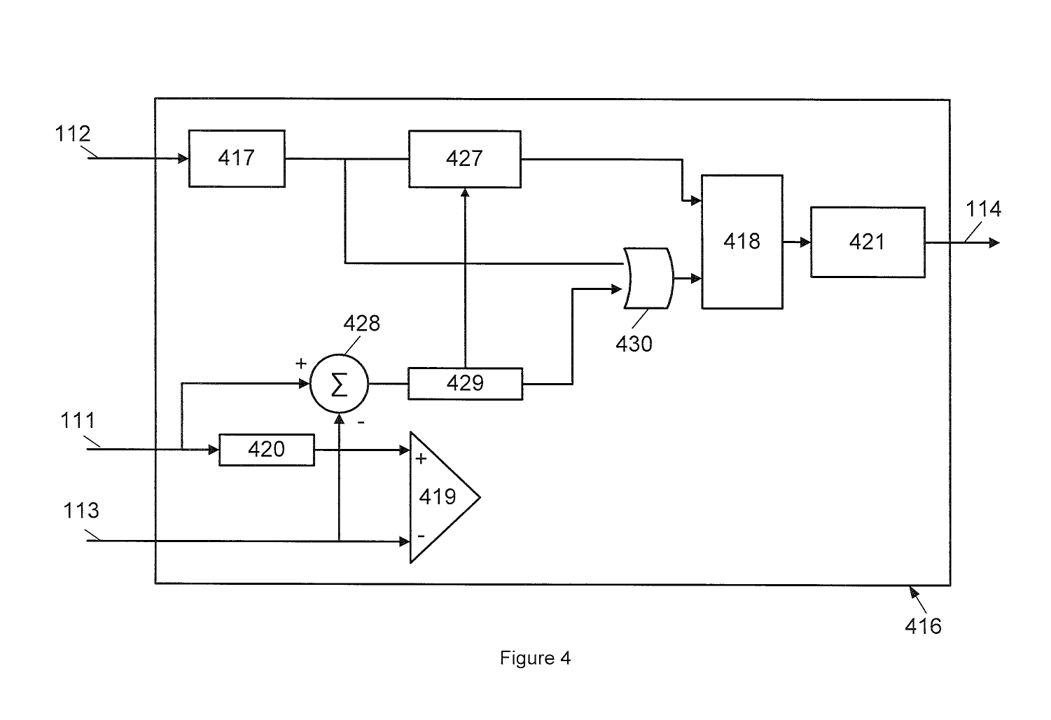

Referring now to FIG. 4, there is illustrated a controller 416 that can be used in place of controller 206, shown in FIG. 2, to provide lagging control in the amplifier power supply circuit 100. In contrast to leading control, which involves closing the regulator 109 at the start (or leading portion) of each half cycle of the AC line source voltage, lagging control involves closing the regulator switch 109 at the end (or lagging portion) of the half-wave line cycle. As described above, relative to leading control, lagging control can result in the regulator switch 109 being self-commutating, which can eliminate the need for voltage snubbing across the regulator switch 109. Accordingly, the regulator switch 109 can be implemented using a SCR or Triac in place of other comparatively less efficient semiconductor devices, such as MOSFETs, IGBTs, and BJTs.

Whereas leading control causes the regulator switch to be closed at or shortly after zero crossings to ensure a small charging current being supplied to the filter capacitor 110, lagging control achieves a similar result by closing the regulator switch 109 ahead of a zero crossing and keeping the regulator switch closed until occurrence of the zero crossing, If it can be accurately predicted at what point during the half-cycle of the line voltage to close the regulator switch 109, an appropriate charging current can be supplied to the filter capacitor 110 to regulate the voltage appearing across the filter capacitor at the reference level. Also, because the charging cycle ends with a zero-crossing, as opposed to a forced break, the charging current naturally decays to zero at or shortly before the pending zero crossing, which makes the regulator switch 109 self-commutating under lagging control. In other words, reversal of the AC line source voltage can naturally bring the charging current in the regulator switch 109 to zero before or as the switch is opened.

The controller 416 can include a zero crossing detector 417, Set/Reset (S/R) latch 418, comparator 419, scalar 420 and level shift/switch driver 421 similar to the controller 206 shown in FIG. 2. However, the controller 416 can further include variable delay generator 427, summer 428, signal averager 429 and OR gate 430. The variable delay generator 427 can be coupled between the zero crossing detector 417 and the set input of the S/R latch 418, and can be configured to receive a control input from the signal averager 429. Summer 428 can be configured to generate an error signal from the capacitor voltage signal 111 and the reference voltage signal 113 and, based upon which, the signal averager 429 generates the control input to the variable delay generator 427. The OR gate 430 can be configured, as explained in more detail below, to multiplex the outputs of the zero crossing detector 417 and the comparator 419 into the reset input of the S/R latch 418.

As before, the zero crossing detector 417 can receive the diode bridge voltage signal 112 and generate a pulse train corresponding to zero crossings detected in the DC full wave rectified voltage signal at the output of the diode bridge 108. However, in accordance with lagging control, the pulse train generated by the zero crossing detector 417 is now delayed in the variable delay generator 427 by a time interval, prescribed by the control input to the variable delay generator 427, before being provided to the set input of the S/R latch 418. Thus, the output of S/R latch 418 is not set to the high voltage immediately after each zero crossing, but instead is delayed in the variable delay generator 427 by an amount determined by the signal averager 429. Different approaches can be followed to implement the variable delay generator 427. For example, the variable delay generator 427 can be implemented using a ramp generator synchronized with the half-line cycle of the AC line source, and a comparator configured to compare the ramp signal with averaged error signal (i.e. the control input to the variable delay generator 429). The amount of the delay can then be fixed through the comparison.

The summer 428 can be configured to subtract the scaled version of the capacitor voltage signal 111 from the reference voltage signal 113 to generate an error signal representative of how much the voltage across the filter capacitor 110 differs from the target level. The averaged error signal generated by the signal averager 429 can be related to a required charge for the filter capacitor 110 in order to maintain its voltage at the regulated level. Given the period of the AC line source, the required charge time can then be related in the variable delay generator 427, for example, by comparison with the ramp signal, to a required delay before closing the regulator switch 109. If the error signal is large, indicating that the voltage of the capacitor filter 110 is well below the reference level, then a longer charge time and correspondingly shorter delay can be calculated. On the other hand, if the error signal is small, indicating the voltage of the capacitor filter 110 is near to its reference level, then a shorter charge time and correspondingly longer delay can be calculated. In this way, the variable delay generator 427 in response to the control input from the signal averager 429 can controllably and predicatively delay closing of the regulator switch 109. A low pass filter or integrator, for example, can be used to implement the signal averager 429.

Ideally, closing of regulator switch 109 can be delayed by an amount calculated so that the voltage of the filter capacitor 110 reaches its reference level exactly at the zero crossings of the AC line source. However, in the event that the delay provided by the variable delay generator 427 is too short, then the voltage across the filter capacitor 110 can reach its reference level before the end of the half-cycle. If the filter capacitor 110 is permitted to continue charging, its voltage may end up exceeding the reference level causing damage to the audio power amplifier 102, which can be designed to have a rated supply voltage. Accordingly, the output of the comparator 419 is coupled into the reset input of the S/R 418 by way of the OR gate 430 to drive output of the S/R latch 418 to the low voltage level, thereby opening the regulator switch 109, if the voltage across the filter capacitor 110 reaches the reference level before the end of the AC line half-cycle. It is noted, however, that this may not necessarily be the case if the switch regulator 108 is implemented using an SCR or Triac. The other input to the OR gate 430 is provided by the zero crossing detector 417 so that, even if the filter capacitor 110 has not completed charging by the end of the AC line half-cycle, the S/R latch 418 will be driven low in any event at the end of each half-cycle.

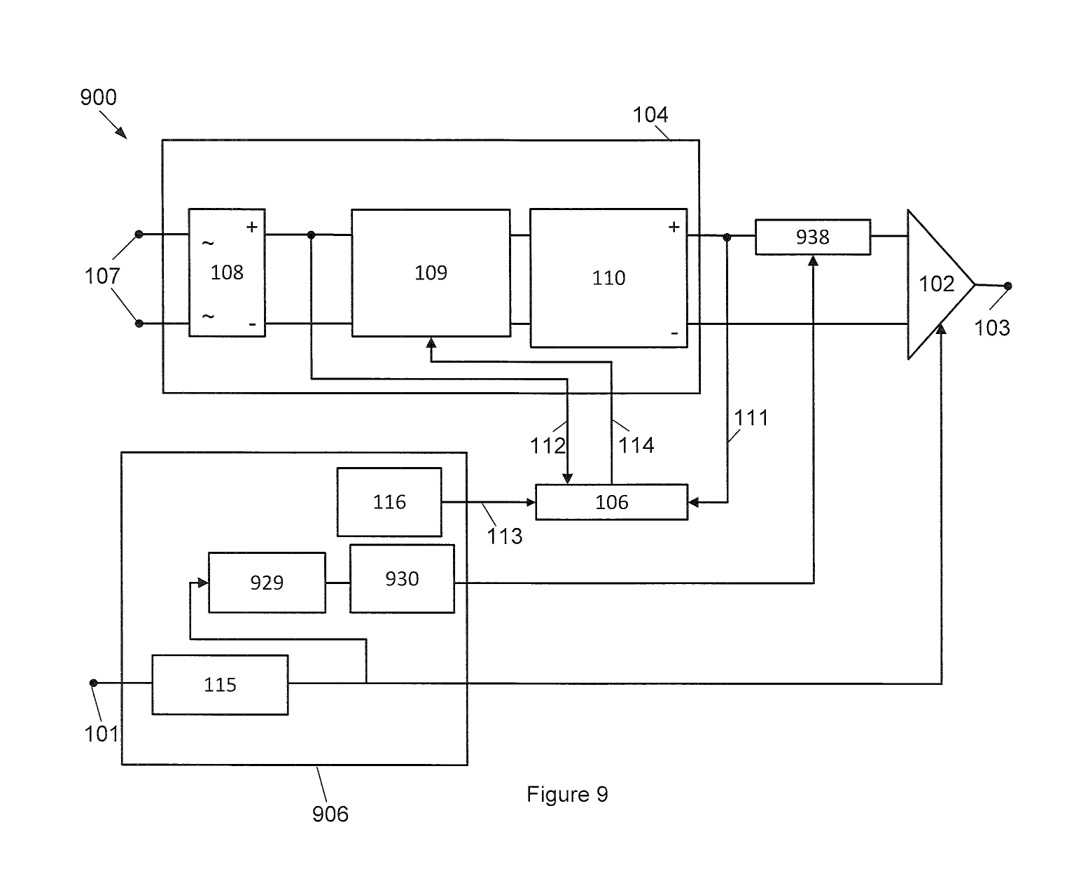

Damage to the audio power amplifier 102 due to over charging of the filter capacitor 110 can be avoided, or at least mitigated, also by inclusion of a series regulator (see, e.g., 938 in FIG. 9) between the filter capacitor 110 and the audio power amplifier 102. The series regulator could be a linear regulator, which is normally saturated and therefore efficient. Power loss would normally also only be associated with the linear regulator when the voltage across the filter capacitor 110 was too high. Alternatively, a semiconductor device, such as a MOSFET or IGBT, could be used to achieve the same general result. When implementing lagging control, in some embodiments, an inductance (for example 25-50 uH) can be added in series with the AC line source to rate limit the line current. This may be used in cases where the AC line source has a very low inductance, or perhaps even capacitative, equivalent impedance. For example, connection of other devices to the same AC line source could cause this effect. But in general, the rate of rise of the line current should be slow enough for the controller 106 to operate.

In embodiments where the regulator switch 109, is implemented using an SCR or Triac, the zero current condition associated with the line voltage reversal will naturally turn of the SCR or Triac. It can also be important for the gate driven by the level shift/switch driver circuit 421 to be off before the zero current condition occurs in the regulator switch 109. If the gate is still being driven when the zero current condition occurs, the regulator switch 109 may remain closed and conducting through the zero crossing and thereby remain closed and conducting for the entire next half-wave line cycle. To avoid this occurrence, in some embodiments, the S/R latch 418 can be replaced with an edge triggered one-shot to drive the Triac or SCR, so that the switch control signal 114 does not lock on at the high voltage level as it would when the S/R latch 418 is used. As will be explained in more detail with reference to FIGS. 8A-8A, the SCRs can typically be included either between the AC line source and the diode bridge 108 or as an integral part of the diode bridge 108 by replacing two opposing diodes in the bridge. Two anti-paralleled SCRs could be included between the AC line source and the diode bridge 108, but in that cause it can be more common to use a Triac instead.

In a further embodiment of the lagging control method a large inductance (such as 1 mH) can be added in series with the AC line. This is possible because the lagging control is self-commutating. Adding this inductance significantly improves the power factor of the AC line current and reduces the crest factor of the current in the regulator switch and filter capacitor. This reduction in crest factor means the rms currents are lower which means the filter capacitor and regulator switch operate more efficiently.

Other more robust methods which would be less sensitive to noise on the AC line can be used to detect the zero cross. For example in either the digital domain or in analog circuitry a phase locked loop could be implemented to lock with the line frequency. The output of the phase locked loop would then be used to detect the zero cross.

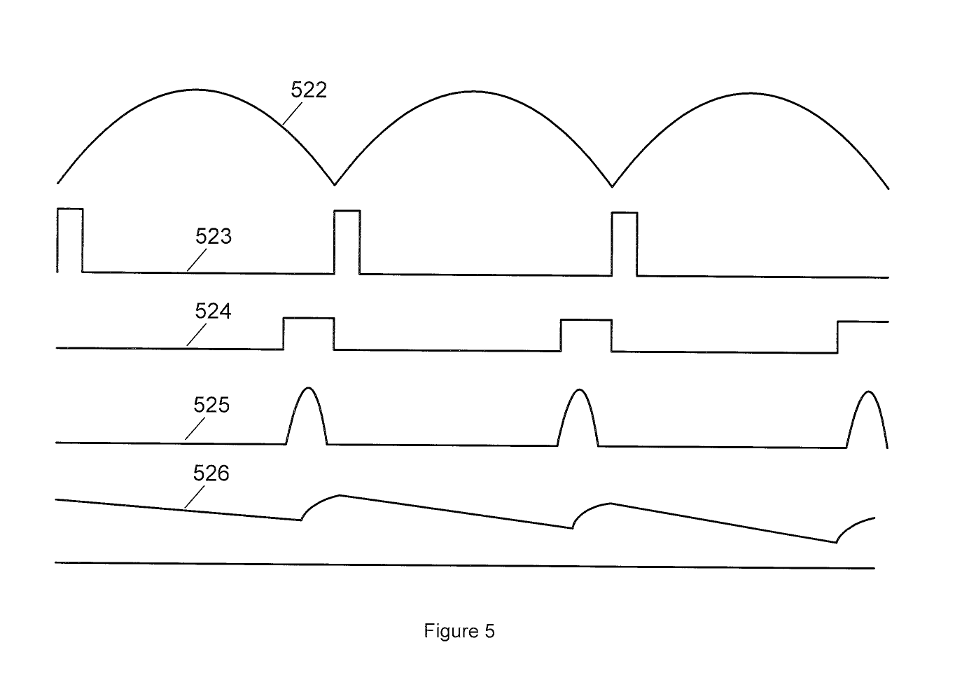

Referring now to FIG. 5, there are illustrated various signal waveforms generated in the amplifier power supply circuit 100 when the controller 416 is used to provide lagging control. Similar to before, waveform 522 represents the DC full wave rectified voltage provided at the output of the diode bridge 108, and waveform 523 represents the output generated by the zero crossing detector 417. Waveform 524 represents the output generated by the S/R latch 418, which, in accordance with lagging control, comprises pulses at the end (“lagging” portion) of each half-cycle. Thus, the waveform 524 is driven to high level at some point in advance of each zero crossing, and then is driven back down to the low level at or near the zero approaches of waveform 522. Waveform 525 represents the charging current supplied to the filter capacitor 110 when the regulator switch 109 is closed. It is evident from FIG. 5 that, waveform 525 rises from zero at the start of each charging period, corresponding to closure of the regulator switch, and is naturally decayed to zero toward the end of the charging period as the waveform 522 approaches zero. In contrast to the abrupt decay of waveform 325 in FIG. 3, the soft turn off of waveform 325 exemplifies one of the advantages of the self-commutating action of the regulator switch 109 as part of lagging control. Finally, as before, waveform 326 can represent the voltage across the filter capacitor 110, which is regulated at the reference level notwithstanding some amount of voltage ripple.

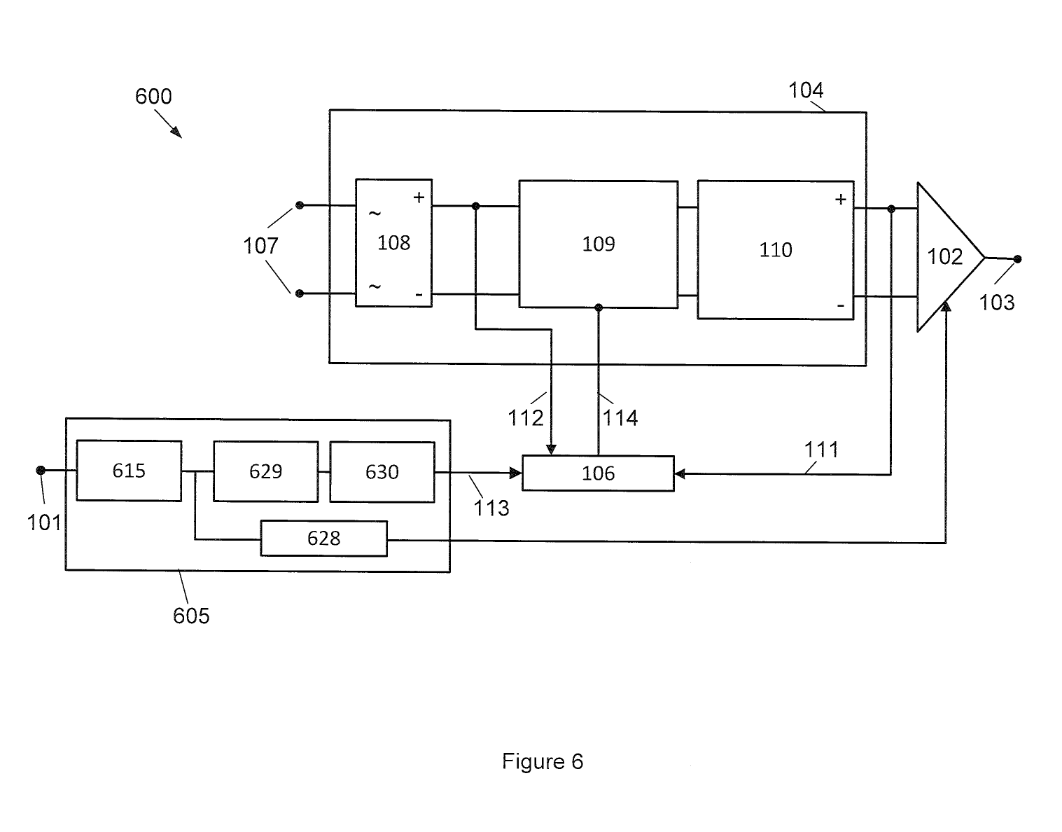

Referring now to FIG. 6, there is illustrated a schematic diagram of an amplitude power supply circuit 600 that uses a floating voltage reference in accordance with embodiments of the present invention. The amplifier power supply circuit 600 is similar to the amplifier power supply circuit 100 shown in FIG. 1, but signal processor 105 has been replaced with signal processor 605. Like components in the two amplifier power supply circuits 100 and 600 are not described in further detail.

The signal processor 605 includes isolation transformer 615, time delay generator 628, absolute value generator 629, and peak detector 630. Isolation transformer 615 can again be used to isolate the audio signal provided to the input terminals of the audio power amplifier 102 and will not be described in further detail. Absolute value generator 629 and peak detector 630 can be serially coupled to the output of the isolation transformer 615 to generate an envelope of the input audio signal as is described, for example, in greater detail in U.S. Pat. No. 7,362,168 incorporated by reference. Briefly, the absolute value generator 629 can be configured to rectify the input audio signal, which is then enveloped using the peak detector 630. The attack and release characteristics of the peak detector 630 can be adjusted to optimize the resulting signal envelope. The rectified and enveloped signal generated by the peak detector 630 can be provided to the controller 106 as the reference voltage signal 113. Thus, the controller 106 can regulate the voltage appearing filter capacitor 110 to follow the envelope of the input audio signal substantially as described in U.S. Pat. No. 7,362,168.

As described herein, the leading and lagging control schemes can result in only one charging period for the filter capacitor 110 per half-cycle. When the reference voltage signal 113 is fixed, as in the amplifier power supply circuit 100, the filter capacitor 110 can reach steady-state (i.e. its regulated level), in which case the filter capacitor 110 should normally have sufficient voltage to supply to the audio power amplifier 102. However, if the reference voltage signal 113 is permitted to float, such as by tracking the envelope of the input audio signal, then sudden changes in reference voltage signal 113 can cause transients in the voltage of the filter capacitor 110. A finite settle time may be associated with these transients before the filter capacitor voltage reacquires the voltage reference.

If an audio signal is applied to the audio power amplifier 102 before the filter capacitor 110 has had time to settle, the audio amplifier 102 may receive an insufficient voltage supply from the filter capacitor 110 to amplify the input audio signal without clipping or other distortion. Time delay generator 628 can be interposed between the isolation transformer 615 and the audio power amplifier 102 to delay application of the input audio signal to the audio power amplifier 628 so that the filter capacitor 110 has sufficient time to charge to the reference level. The duration of the delay is adjustable and can be defined, for example, by reference to the period of the AC line source voltage. In some embodiments, the input audio signal can be delayed by one half-cycle of the AC line source, in which case the power regulator 104 can be afforded an entire half-cycle to catch up the voltage on the filter capacitor to the reference level. Of course, other delay lengths are possible as well. In any event, inclusion of the time delay generator 628 can afford the power regulator 104 sufficient response time to regulate voltage in the filter capacitor 110.

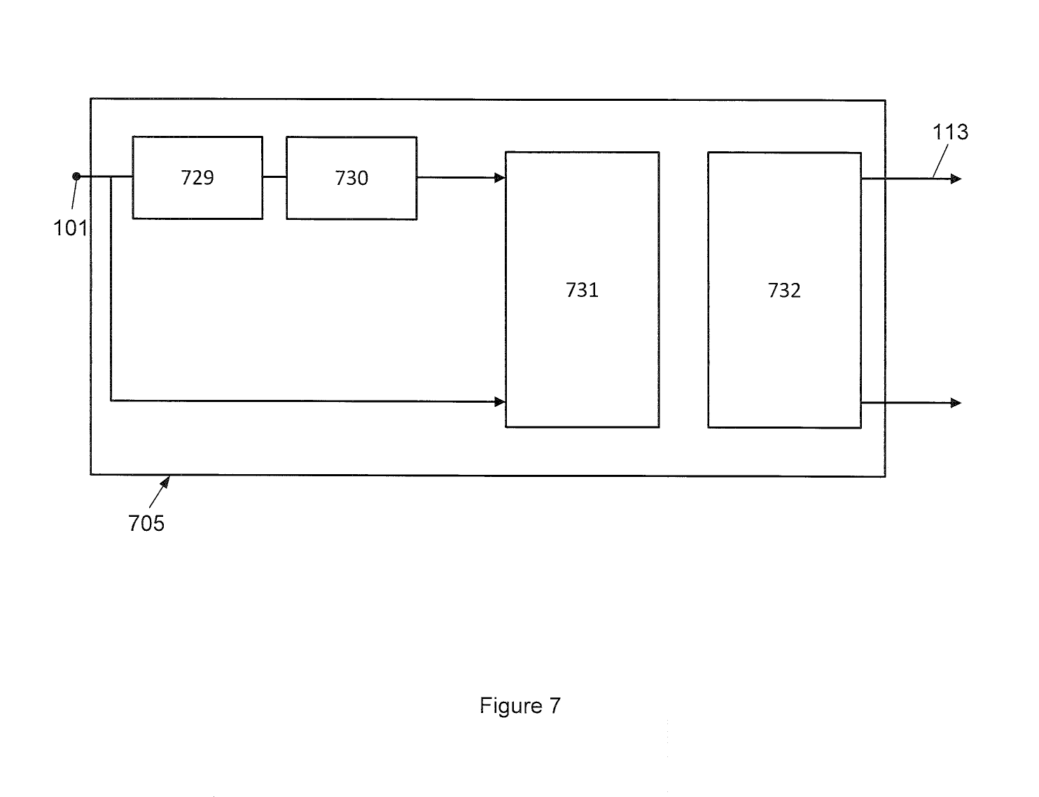

Referring now to FIG. 7, there is illustrated a signal processor 705 incorporating wireless transmission of data signals in accordance with embodiments of the present invention. The signal processor 705 comprises an absolute value generator 729 and a peak detector 730, similar to the signal processor 605, but further includes wireless transmitter 731 and wireless receiver 732. The absolute value generator 731 is coupled to the audio input terminal 101, while the output of the peak detector 730 is coupled to a control path in of the wireless transmitter 731. The combination of the absolute value generator 729 and peak detector 730 can again be configured to generate a rectified, enveloped version of the input audio signal as described more fully in U.S. Pat. No. 7,362,168 incorporated by reference.

A control path out of the wireless receiver 732, which receives wireless transmissions from the control path in of the wireless transmitter 731, can be used to provide the enveloped audio signal generated by the peak detector 730 to the controller 106 as the voltage reference signal 113. The audio input terminal 101 is also coupled to an audio in of the wireless transmitter 731 used to transmit the input audio signal to an audio out of the wireless receiver 732. Thus, separate control and audio paths can be defined in the wireless transmitter 731 and wireless receiver 732. The audio signal received at the audio out of the wireless receiver 732 can be provided to the audio power amplifier 102.

Signal processor 705 can be used in some embodiments as an alternative to signal processor 605 as will be explained. In signal processor 705, the combination of the wireless transmitter 731 and the wireless receiver 732 can replace the isolation transformer 615 for providing isolation of the input audio signal. Moreover, inherent delay in the audio transmission path of the combination wireless transmitter 731 and wireless receiver 732, relative to the control path, can simulate the time delay generator 628. Achieving differential delay between the input audio signal and the reference voltage signal 113 during wireless transmission can be achieved according to different approaches. For example, a fast transmission path can be provided for the reference voltage signal 113 that has low bandwidth and low resolution, as would be typical in many wireless systems. A comparatively slow transmission path that has comparatively high bandwidth and resolution can then be provided for the audio path, as would again be typical in many wireless systems. The differential delay between the control and audio paths can be controlled by selection of the two respective transmission paths.

Referring now to FIGS. 8A-8A, there are illustrated schematic diagrams showing alternative configurations of a power regulator circuit having an integrated diode bridge, switch regulator, filter capacitor combination. In the power regulator circuit 800, illustrated in FIG. 8A, MOSFET 801 coupled on the positive terminal of the filter capacitor 110 at the output of the diode bridge 108 acts as the regulator switch 109. In response to its gate input, the MOSFET 801 can alternately connect and disconnect the filter capacitor 110 to the diode bridge 108. In power regulator circuit 805, illustrated in FIG. 8B, the diode bridge 108′ incorporates a pair of SCRs 806 on opposite lines of the diode bridge 108′. The pair of SCRs 806 can act as the regulator switch 109 in the power regulator circuit 805 by selectively coupling opposite lines of the diode bridge to the filter capacitor 110. Finally, in power regulator circuit 810, illustrated in FIG. 8C, Triac 811 coupled to input line 2 can act as the switch regulator 109 for filter capacitor 110. Of course, it should be appreciated, that these power regulator circuits are exemplary only, and that other configurations and combinations of circuit elements can be used to the same effect.

Referring now to FIG. 9, there is illustrated a schematic diagram of an amplifier power supply circuit 900 that utilizes a supplemental regulator in accordance with embodiments of the present invention. In the amplifier power supply circuit 900, regulator 938 is used to couple the filter capacitor 110 to the audio power amplifier 102. The regulator 938 receives a control input generated by the signal processor 906, which can be an envelope of the input audio signal. Accordingly, absolute value generator 929 and peak detector 930 can combine to generate the control input for the regulator 938. Signal processor 906 can then additionally include fixed reference generator 116 to generate the voltage reference signal 113 provided to the controller 106 for regulating voltage in the filter capacitor 110.

In some embodiments, the regulator 938 can be an efficient switching regulator operable to down regulate a high voltage from the filter capacitor 110 to levels suitable for efficient operation of the audio power amplifier 102, as described in U.S. application Ser. No. 12/647,022 incorporated by reference. On account of the voltage step down provided by the regulator 938, the filter capacitor 110 can then be regulated at a much higher reference level, for example above the rated limits of the audio power amplifier 102, than it could have been without inclusion of the regulator 938. At these higher voltage levels, the filter capacitor 110 can receive lower RMS charging current from the regulator switch 109 because the higher regulated voltage of the filter capacitor 110 can result in longer close times for the regulator switch 109.

Sometimes the RMS current and/or peak current in the regulator switch 109 can be managed in order to protect the power semiconductor device underlying the regulator switch 109. However, limiting current flow through the regulator switch 109 can in turn limit the available power for the audio power amplifier 102. But by inclusion of the regulator 938 to decouple the filter capacitor 110 from the audio power amplifier 102, as in U.S. application Ser. No. 12/175,573, the maximum available output power for a given RMS and/or peak current in the regulator switch 109 can be increased. In such case, the filter capacitor 110 can be sized appropriate to provide sufficient available power for sudden bursts of output audio, while at the same time managing the volume of the output audio so that the average out power does not exceed the output power capability of the regulator switch 109.

As described more fully in U.S. application Ser. No. 12/175,573, in some embodiments, an efficient switching amplifier can be used alternatively to decouple the output amplifier load from the filter capacitor 110. Thus, in these embodiments, the BTL amplifier could be replaced with a switching amplifier. If the switching amplifier is selected to have a high voltage rating, the filter capacitor can again be operated well above the desired amplifier output voltage to avoid clipping the amplified output audio signal amplifier. The filter capacitor 110 can be regulated at a fixed reference level selected so to maintain stored energy in the filter capacitor 110 substantially as described in U.S. application Ser. No. 12/175,573.

The above described embodiments should be understood as being exemplary only and that various modifications and variations are possible. For example, because audio and wireless systems commonly involve a mixture of analog and digital signals, different signal paths in the described embodiments can be implemented using a mixture and analog and digital components as the case may be.

In some embodiments, a Class D amplifier similar to that described in U.S. Pat. No. 7,362,168 can be used in place of a BTL amplifier.

In some embodiments, the filter capacitor 110 can be split into two capacitors connected in a bias circuit to establish a bias ground. This would allow the audio power amplifier 102 to be configured for Push-Pull operation rather than the described bridge configuration.

In some embodiments, a hybrid leading-lagging control could be utilized, wherein the controller 106 could select between the leading and lagging control schemes based on different conditions or parameters. For example, leading control could be selected when the average power from the audio power amplifier 102 is low or the system is idle or in a standby mode. On the other hand, lagging control could be utilized when the power demands on the audio power amplifier 102 are high. Control logic including optional hysteresis could be employed by the controller 106 to make the selection.

In some embodiments, a current sensor can be included so that, when the charging current in the regulator switch 109 exceeds a safe level, the switch control signal 114 can be driven low to open the regulator 109 and clear the overcurrent. However, it should be appreciated that a Triac or SCR should not be used in these embodiments to implement the regulator switch 109, as these semiconductor devices do not drop current instantaneously.

Embodiments of the present invention have been described herein by way of example only. Various additional modifications and variations to these exemplary embodiments may be apparent without departing from the scope of the invention, which is limited only by the appended claims.

We claim:

1. An amplifier power supply circuit comprising:
a power regulator comprising:
a signal rectifier coupled to an AC power voltage source to receive an AC line voltage signal and to provide a rectified line voltage signal and a rectifier voltage signal;
a filter capacitor;
a controllable switch for selectively coupling the rectified line voltage signal to the filter capacitor to charge the filter capacitor in response to a switch control signal, wherein the capacitor provides a capacitor voltage signal and an amplifier supply voltage signal corresponding to the charge across the filter capacitor;
a reference signal generator for generating a reference voltage signal;
a controller for generating the switch control signal in response to the rectifier voltage signal, the capacitor voltage signal and the reference voltage signal; and
an audio power amplifier coupled to the input terminal to receive the audio input signal and to the filter capacitor to receive the amplifier supply voltage signal and for generating an amplified audio signal.

2. The amplifier power supply circuit of claim 1 wherein the audio power amplifier is selected from the group consisting of:
a bridged transistor linear amplifier;
a push-pull linear amplifier; and
a class D amplifier.

3. The amplifier power supply circuit of claim 1 wherein the reference signal is fixed reference signal.

4. The amplifier power supply circuit of claim 1 wherein the reference signal is floating reference signal corresponding to the audio input signal.

5. The amplifier power supply circuit of claim 1 wherein the reference signal is floating reference signal corresponding to the audio input signal.

6. The amplifier power supply circuit of claim 1 further including an input signal isolation block for providing an isolated input signal, wherein the audio power amplifier generates the amplified signal corresponding to the isolated power signal.

7. The amplifier power supply circuit of claim 1 wherein the controller generates the switch control signal to start charging the filter capacitor in response to a zero crossing of the AC line voltage signal and to stop charging the filter capacitor when the charge on the filter capacitor corresponds to the reference voltage signal.

8. The amplifier power supply circuit of claim 1 wherein the controller generates the switch control signal to start charging the filter capacitor in advance of a zero crossing of the AC line voltage signal and to stop charging the filter capacitor in response to the zero crossing.

9. A method of operating an amplifier power supply circuit, the method comprising:
rectifying an AC line voltage and generating a rectified line voltage signal and a rectifier voltage signal;
coupling the rectified line voltage signal to a filter capacitor in response to a switch control signal;
providing a capacitor voltage signal corresponding to the voltage across the capacitor;
providing a reference voltage signal;
generating the switch control signal in response to the rectifier voltage signal, the capacitor voltage signal and the reference voltage signal;
providing an amplifier coupled to the filter capacitor, wherein the amplifier receives an amplifier supply voltage signal from the filter capacitor; and
at the amplifier, amplifying an audio input signal to provide a corresponding audio output signal.

10. The method of claim 9 wherein the switch control signal is generated to couple the rectified line voltage signal to the filter capacitor in response to a zero crossing of the AC line voltage and to decouple the rectified line voltage signal when the charge on the filter capacitor corresponds to the reference voltage.

11. The method of claim 9 wherein the switch control signal is generated to couple the rectified line voltage signal to the filter capacitor in advance of a zero crossing of the AC line voltage and to decouple the rectified line voltage signal in response to the zero crossing.
